(19) United States
(12) Patent Application Publication
(10) Pub. No.: US 2005/0093155 A1
(43) Pub. Date: May 5, 2005

(54) Barrier layer including a titanium nitride liner for a copper metallization layer including a low-k dielectric

(76) Inventors: Volker Kahlert, Dresden (DE); Michael Friedemann, Dresden (DE)

Correspondence Address: WILLIAMS, MORGAN & AMERSON, P.C., 10333 RICHMOND, SUITE 1100, HOUSTON, TX, 77042, US

(21) Appl. No.: 10/865,199

(22) Filed: Jun. 10, 2004

(30) Foreign Application Priority Data
Oct. 31, 2003 (DE) 103 51 005.2

(51) Int. Cl. H01L 23/48

(52) U.S. Cl. 257/751; 257/761

(57) ABSTRACT

An improved barrier technology for interconnect features, especially for copper-based interconnects, is provided. A thin titanium nitride liner is conformally deposited by chemical vapor deposition so as to reliably cover all inner surfaces of the interconnect features, even if formed within a porous material, and thus provides a surface area having improved wettability for the deposition of a subsequent barrier material. Hence, the step coverage of a sputter deposition technique, typically used for tantalum-based barrier layers, may be successfully used in combination with the titanium nitride liner, thereby improving the wetting properties for the subsequent copper seed deposition compared to a tantalum-based barrier layer formed by ALD. Moreover, the provision of a CVD titanium nitride liner in combination with a sputter deposited barrier layer assures a significantly higher throughput compared to the conventional atomic layer deposition approach.

### BACKGROUND OF THE INVENTION

1. Field of the Invention

Generally, the present invention relates to the formation of integrated circuits, and, more particularly, to the formation of metallization layers including highly conductive metals, such as copper, embedded into a dielectric material having low permittivity to enhance device performance.

2. Description of the Related Art

In an integrated circuit, a huge number of circuit elements, such as transistors, capacitors, resistors and the like, are formed in or on an appropriate substrate, usually in a substantially planar configuration. Due to the large number of circuit elements and the required complex layout of the integrated circuits, generally, the electrical connection of the individual circuit elements may not be established within the same level on which the circuit elements are manufactured, but requires one or more additional “wiring” layers, also referred to as metallization layers. These metallization layers generally include metal-containing lines, providing for the inner-level electrical connection, and also include a plurality of inter-level connections, also referred to as vias, filled with an appropriate metal and providing the electrical connection between two neighboring stacked metallization layers, wherein the metal-containing lines and vias may also be commonly referred to as interconnects.

Due to the continuous shrinkage of the feature sizes of circuit elements in modem integrated circuits, the number of circuit elements for a given chip area, that is the packing density, also increases, thereby requiring an even larger increase in the number of electrical interconnections to provide the desired circuit functionality. Therefore, the number of stacked metallization layers usually increases as the number of circuit elements per chip area becomes larger. The fabrication of a plurality of metallization layers entails extremely challenging issues to be solved, such as mechanical, thermal and electrical reliability of up to twelve stacked metallization layers that may be employed on sophisticated aluminum-based microprocessors. However, semiconductor manufacturers are increasingly replacing the well-known metallization metal aluminum by a metal that allows higher current densities and hence allows a reduction in the dimensions of the interconnections. For example, copper is a metal generally considered to be a viable candidate for replacing aluminum due to its superior characteristics in view of higher resistance against electromigration and significantly lower electrical resistivity when compared with aluminum. Despite these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD), and also may not be effectively patterned by the usually employed anisotropic etch procedures. Consequently, in manufacturing metallization layers including copper, the so-called damascene technique (single and dual) is therefore preferably used wherein a dielectric layer is first applied and then patterned to receive trenches and vias, which are subsequently filled with copper. A further major drawback to the use of copper is its propensity to readily diffuse in many dielectric materials such as silicon dioxide, which is a well-established and approved dielectric material in fabricating integrated circuits.

It is therefore necessary to employ a so-called barrier material in combination with a copper-based metallization to substantially avoid any diffusion of copper into the surrounding dielectric material, as copper may readily migrate to sensitive semiconductor areas, thereby significantly changing the characteristics thereof. The barrier material provided between the copper and the dielectric material should, however, in addition to the required barrier characteristics, exhibit good adhesion to the dielectric material as well as to the copper to impart superior mechanical stability to the interconnect and should also have as low an electrical resistance as possible so as to not unduly compromise the electrical properties of the interconnection.

With the continuous shrinkage of features sizes of the circuit elements, the dimensions of the interconnects is also reduced, thereby also necessitating a reduced layer thickness of the barrier materials in interconnects so as to not unduly consume precious space of the actual metal that exhibits a considerably higher conductivity compared to the barrier material. Hence, complex barrier technologies are required to support further device scaling, wherein the usage of low-k dielectric materials may even impart further increased constraints to the barrier layer, as will be described for a typical process technique for sophisticated copper-based integrated circuits with reference to FIGS. 1a-1c.

FIG. 1a depicts a schematic cross-sectional view of a semiconductor structure 100 comprising a substrate 101, for example a semiconductor substrate, bearing a plurality of individual circuit elements (not shown), such as transistors, resistors, capacitors and the like. The substrate 101 is representative of any type of appropriate substrate with or without any additional circuit elements and may, in particular, represent sophisticated integrated circuit substrates having included therein circuit elements with critical feature sizes in the deep submicron range. A first dielectric layer 102 is formed above the substrate 101 and includes a conductive region 104, for instance an interconnect feature comprised of a metal line 103, such as a copper line, and a first barrier layer 106 comprised of tantalum, and a second barrier layer 105 comprised of tantalum nitride. The dielectric layer 102 and the interconnect feature 104 may represent a first metallization layer. A second dielectric layer 107 comprised of a dielectric material of low permittivity, as is typically used for obtaining reduced parasitic capacitances between adjacent metal lines, is formed over the first dielectric layer 102 and has formed therein a trench 109 and a via 108 connecting to the metal line 103. A first barrier layer 110 is formed on inner surfaces of the via 108 and the trench 109.

A typical process flow for forming the metallization structure 100 as shown in FIG. 1a may include the following steps, wherein, for the sake of simplicity, only the formation of the second metallization layer, i.e., the second dielectric layer 107 and the metal interconnect feature to be formed therein, will be described in detail as the processes in forming the interconnect feature 104 in the first dielectric layer 102 may substantially involve the same process steps. Thus, after planarizing the dielectric layer 102, including the interconnect feature 104, the dielectric layer 107 is deposited by well-known deposition methods, such as plasma enhanced CVD, spin-on techniques and the like, wherein, typically, an etch stop layer (not shown) may be deposited prior to the formation of the second dielectric layer 107. Subsequently, the dielectric layer 107 is patterned by well-known photolithography and anisotropic etch techniques, wherein an intermediate etch stop layer (not shown) may be used in patterning the trench 109. It should further be noted that different approaches may be employed in forming the trench 109 and the via 108, such as a so-called via first trench last approach, or a trench first via last approach, wherein, in the former approach, the via 108 may be filled with metal prior to the formation of the trench 109. In the present example, a so-called dual damascene technique is described in which the trench 109 and the via 108 are simultaneously filled with metal. After the formation of the via 108 and the trench 109, the first barrier layer 110, for instance comprised of tantalum nitride, may be deposited by advanced physical vapor deposition (PVD) or ionized PVD (IPVD) techniques for less critical applications, i.e., for devices requiring a layer thickness of 20-50 nm. Generally, the deposition of the thin barrier layer 110, typically with a thickness in the above range, in a reliable manner throughout the entire inner surfaces of the trench 109 and the via 108, wherein in particular the via 108 may have a large aspect ratio, requires advanced sputter tools that allow effective control of the directionality of the target atoms. Generally, it is desirable to select the deposition parameters so as to obtain a reliable coverage of the sidewalls and bottom surfaces of the trench 109 and the via 108 at a minimum thickness of the layer 110 so that only a minimum amount of space is “consumed” by the layer 110. Increasing the thickness of the barrier layer 110 would otherwise unduly compromise the electrical conductivity of the interconnect to be formed in the via 108 and the trench 109, especially when the feature sizes of the via 108 are scaled to 0.2 μm and less.

In highly advanced devices requiring a barrier layer thickness of approximately 10 mn or even less, these techniques may not readily provide the required sidewall coverage, especially due to the fact that many of the low-k dielectric materials used may have a porous structure, which may therefore lead to the formation of openings on the sidewalls of the via 108 and on the sidewalls and the bottom of the trench 109. Thus, the resulting “topography” also has to be reliably covered by the barrier layer 110. The advanced sputter techniques usually employed for tantalum-based barrier layers may therefore not be applied with the desired efficiency, since these techniques are highly directional in nature and may not provide the capability for efficiently filling voids at sidewalls of the via 108 without requiring an unduly overall layer thickness. Since CVD processes, which per se exhibit superior step coverage compared to PVD deposition, are not available for an acceptable temperature range for tantalum-based layers, atomic layer deposition (ALD) has been developed for tantalum nitride so as to provide extremely thin barrier layers on the order of 20 Å with the required coverage of the via sidewalls. Hence, in extremely scaled semiconductor devices, the barrier layer 110 may typically be formed by ALD with a thickness of, for instance, 5 nm and less.

FIG. 1b schematically shows the semiconductor structure 100 with a copper seed layer 112 formed on the structure 100 and within the trench 109 and the via 108. As previously noted, the copper seed layer 112 may be deposited by sputter deposition. The provision of the copper seed layer 112 may be advantageous in view of the crystallinity of the subsequently electrochemically deposited bulk copper compared to a direct provision of the copper on the barrier layer 110. However, the tantalum nitride barrier layer 110, when deposited by ALD, although exhibiting the desired coverage and layer thickness, shows a significantly reduced wettabilitiy for the copper seed layer 112 compared to a sputter-deposited tantalum nitride layer. As a consequence, portions or defects 111 may result, for instance at critical locations within the via 108 having a reduced seed layer thickness, thereby adversely affecting the subsequent deposition of copper on the semiconductor structure 100 by, for example, electroplating.

FIG. 1c schematically shows the semiconductor structure 100 after completion of the copper deposition and the subsequent removal of excess copper by, for instance, chemical mechanical polishing (CMP). Copper 113 is filled in the trench 109 and the via 108, wherein the portions 111 of insufficiently deposited copper seed material may cause irregularities in the deposited copper, thereby compromising the conductivity and/or the reliability of the via 108.

In view of the above-identified problems, there is a need for an improved barrier layer allowing the formation of more reliable metal interconnects, especially of copper interconnects, in highly scaled semiconductor devices.

### SUMMARY OF THE INVENTION

Generally, the present invention is directed to a technique for forming a conductive barrier layer for an interconnect feature that provides superior wettabilitiy and coverage for a subsequently deposited metal, such as copper, while at the same time assuring high throughput in that currently available deposition tools may effectively be utilized. To this end, a thin titanium nitride liner is conformally formed by CVD, which reliably covers sidewalls of vias and trenches, even when formed in low-k materials and porous materials, wherein the liner may then serve as an efficient wetting layer for a subsequent material, such as a tantalum-based barrier layer or a metal for forming metal lines and contacts.

According to one illustrative embodiment of the present invention, a semiconductor structure comprises a metal region positioned in a dielectric layer. A first barrier layer comprised of titanium nitride is disposed between the dielectric and the metal region. Additionally, the structure comprises a second barrier layer disposed between the first barrier layer and the metal region.

According to another illustrative embodiment of the present invention, a semiconductor structure comprises an interconnect feature that is at least partially embedded in an opening in a layer of dielectric material. The interconnect feature includes a first barrier layer comprised of titanium nitride that is formed on sidewalls of the interconnect feature. The interconnect feature comprises at least one further barrier material formed between the first barrier layer and the interconnect feature.

According to still a further illustrative embodiment of the present invention, a method comprises depositing a titanium nitride liner over a dielectric layer having an opening formed therein for an interconnect feature. Moreover, a barrier layer is formed on the deposited titanium nitride liner in the opening and the opening is finally filled with a metal.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show cross-sectional views of a semiconductor structure including an interconnect feature formed in a low-k dielectric material, wherein irregularities in the metal may be created by providing a barrier layer by ALD according to a conventional technique; and

FIGS. 2a-2d schematically show cross-sectional views of a semiconductor structure including an interconnect feature, in which a barrier layer is formed on the basis of a titanium nitride liner that is deposited in a highly conformal manner on the sidewalls of vias and trenches in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

As previously explained, the reduced wettabilitiy of highly conformally ALD deposited barrier layers on the basis of tantalum and/or tantalum nitride, as are typically used for extremely scaled semiconductor devices having interconnect vias of 0.1 μm diameter and less, may result in degraded performance and/or reliability due to irregularities in the metal structure. The present invention is based on the idea to maintain presently well-established and approved process techniques, such as sputter deposition of tantalum and tantalum nitride, while nevertheless providing the potential for forming extremely thin barrier layers as required for advanced semiconductor devices. To this end, an extremely thin titanium nitride liner is provided prior to the actually desired barrier material, which in currently used copper-based process sequences is tantalum and/or tantalum nitride, wherein the titanium nitride liner, deposited by approved CVD techniques, serves as a wetting layer for the subsequently deposited barrier material and/or for the subsequently deposited metal. Titanium nitride with a thickness of several tens of nanometers (e.g., 50-100 nm) has been intensively used as barrier material for aluminum and copper and other materials due to its diffusion blocking characteristics. In order to provide a highly conformal titanium nitride layer, the CVD technique is the preferred method, wherein titanium nitride may be deposited at relatively low temperatures, for instance in the range of 350-450° C. from organo-metallic precursors, such as tetrakis-(dimethylamido) titanium (TDMAT) or from tetrakis-(diethylamido) titanium (TDEAT). The deposition with these precursors, however, results in a relatively high resistivity of the titanium nitride layer due to a high amount of impurities, mostly carbon, that are incorporated into the titanium nitride layer. For this reason, a plasma treatment on the basis of nitrogen or ammonia is typically performed so as to efficiently remove the contaminants, thereby improving the conductivity of the titanium nitride layer. During the plasma treatment, the thickness of the titanium nitride layer may be reduced to approximately 40% of the thickness as deposited, wherein the thickness reduction substantially occurs on horizontal surface portions, such as the bottom of vias and trenches, as the plasma treatment is a substantially directional process. Since the removal of contaminants and the thickness reduction on sidewalls of vias is significantly less efficient, this conventional approach is less than desirable for extremely scaled devices requiring highly conductive and thin barrier layers on sidewalls of high aspect ratio vias.

Contrary to the conventional titanium nitride deposition technique, the present invention is based on the concept of providing an extremely thin but highly conformal titanium nitride liner, which may even reliably cover any voids formed by porous materials within trenches and vias and which may then receive a desired barrier material, such as tantalum and/or tantalum nitride in a form that allows an efficient deposition of the subsequent metal, such as copper.

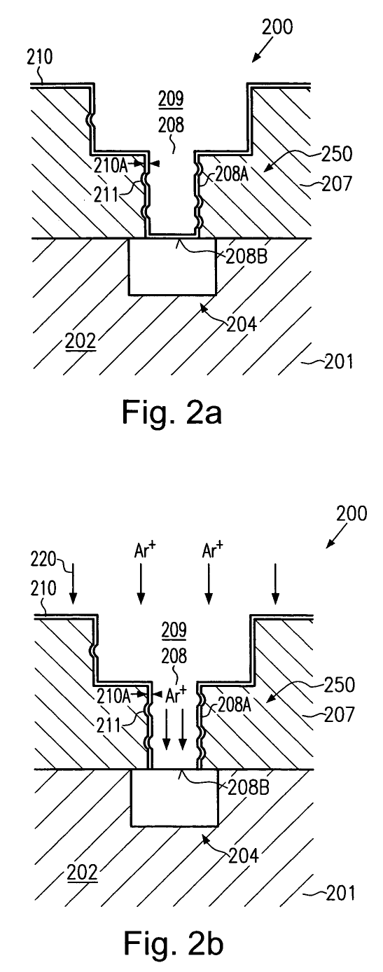

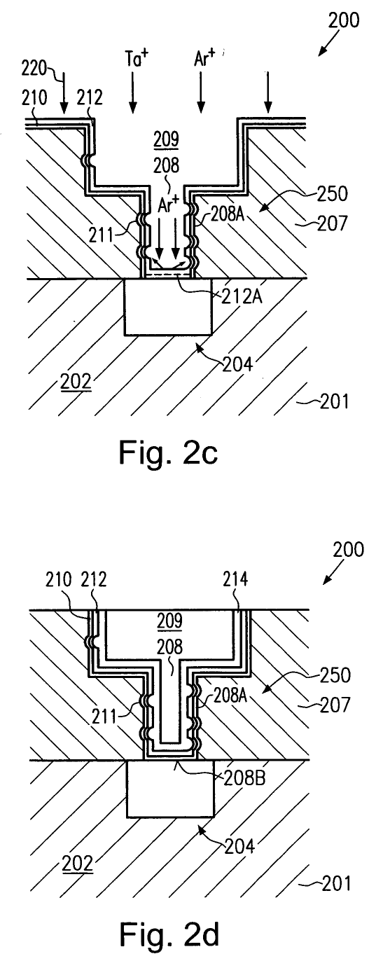

With reference to FIGS. 2a-2d, further illustrative embodiments of the present invention will now be described in more detail. FIG. 2a schematically shows a cross-sectional view of a semiconductor structure 200 including an interconnect feature 250 that may be represented by a trench 209 and a via 208. The interconnect feature 250 is formed in a layer of dielectric material 207, which may be comprised, in particular embodiments, of a low-k dielectric material. In this respect, a dielectric material may be considered as having a low dielectric constant k when the value thereof is 3.0 or less. Typical low-k dielectric materials may include SiCOH, HSQ, MSQ and other polymeric organic materials. Typically, some or all of these materials may be provided in a substantially porous structure so that voids 211 may be formed in the trench 209 and the via 208, for instance on sidewalls 208a and 209a thereof. It should be appreciated that the present invention is particularly advantageous in the context of low-k dielectric materials and especially for porous low-k dielectric materials, wherein, however, the present invention may be applied to any dielectric material, such as silicon dioxide, silicon nitride and the like, if considered appropriate. The dielectric layer 207 is formed above a substrate 201, which may be any appropriate substrate bearing further circuit elements, such as transistors and the like, which for convenience are not illustrated in FIG. 2a. The substrate 201 may have a conductive region 204 formed thereon that is located in a dielectric layer 202, wherein the conductive region 204 may represent an interconnect feature of a lower lying metallization layer or may represent a contact region of a circuit element, such as a transistor and the like. Hence, the via 208 connects with its bottom portion 208b to the conductive region 204 so as to establish, after completion of the interconnect feature 250, an electrical connection from the conducive region 204 to the trench 209. It is to be noted that the interconnect feature 250 is of illustrative nature only and the present invention may be readily applied to other configurations of interconnect features, such as single vias or single trenches, and the like.

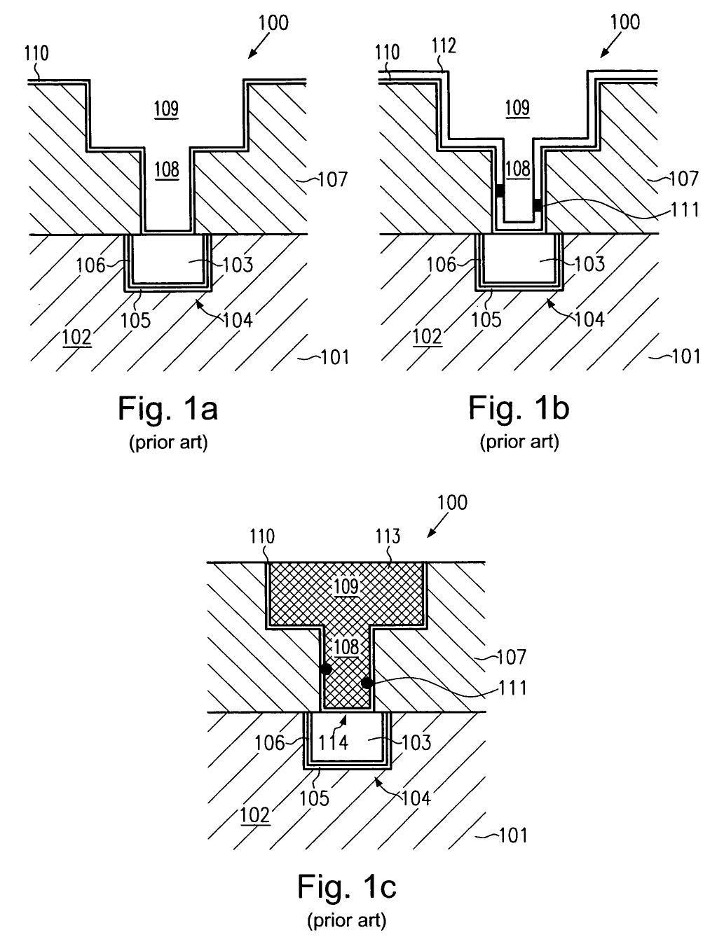

A typical process flow for forming the semiconductor structure 200 as shown in FIG. 2a may comprise the following processes. After forming the conductive region 204 and the dielectric layer 202 on the substrate 201, which may be accomplished by well-established process techniques, the dielectric layer 207 is deposited, for instance by chemical vapor deposition and/or spin-on techniques in a similar fashion as is already explained in detail with reference to FIG. 1a. Thereafter, the interconnect feature 250 is patterned by advanced lithography and sophisticated etch techniques, as is also described with reference to FIG. 1a. Next, the titanium nitride liner 210 is formed by chemical vapor deposition, wherein process parameters are controlled so as to adjust a thickness 210a of the titanium nitride liner 210 to a value as is required by the design specifications. In particular embodiments, the thickness 210a is adjusted to approximately 20 Å or less, and, in one specific embodiment, the thickness 210a is selected to be approximately 15 Å or less. In one illustrative embodiment, the thickness 210a is adjusted within a range of approximately 10-15 Å. The chemical vapor deposition may be carried out with the above-specified precursor materials in any appropriate deposition tool that is currently available for semiconductor production. For instance, an Endura™, available from Applied Materials, may be used efficiently for depositing the titanium nitride liner 210. Due to the isotropic nature of the material deposition during the CVD process, the voids 211 are reliably covered by the liner 210, even at the sidewalls 208a of the via 208, thereby assuring an efficient diffusion barrier effect, even if an actually desired barrier material to be applied on the titanium nitride liner 210 may not exhibit as high a degree of step coverage as would be necessary so as to completely fill or cover the voids 211 when the titanium nitride liner 210 would not be provided, as in the conventional case.

As previously explained, the CVD deposited titanium nitride liner 210 may exhibit an increased resistivity owing to the incorporation of contaminants, such as carbon and the like. Hence, the liner 210 may be reduced in thickness or even substantially completely removed from the bottom portion 208b when the increased resistivity is considered inappropriate. In other embodiments, it may be acceptable, due to the extremely small thickness of the liner 210, to substantially maintain the liner 210 at the bottom 208b. In other illustrative embodiments, a plasma treatment in a nitrogen or ammonia atmosphere may be carried out, wherein, as previously explained and due to the substantially directional nature of the plasma treatment, mainly horizontal portions, such as the liner at the bottom 208b, are treated, whereby the thickness of the liner 210 (as well as the amount of contaminants contained therein) is also significantly reduced.

In one particular embodiment, the plasma treatment is omitted and a thickness reduction of the liner 210 at the bottom 208b is achieved prior to or during a deposition of a second barrier material, as will be described with reference to FIG. 2b. By omitting the plasma treatment of the titanium nitride liner 210, the throughput and tool utilization of the CVD deposition tool may be increased. For instance, for the above-specified Endura™ tool of Applied Materials, a deposition sequence may be performed by de-gassing the substrate 201 at a temperature of approximately 300° C. for a time interval of approximately 60 seconds. Thereafter, the deposition is initiated at a temperature within a range of approximately 350-400° C., wherein the thickness 210a in the range of 10-15 Å results in a throughput of approximately 40-60 substrates per hour.

FIG. 2b schematically shows the semiconductor structure 200 with the liner 210 substantially removed from the bottom portion 208b of the via 208. To this end, the semiconductor structure 200 may be inserted into a sputter deposition tool and may be exposed to a highly directional ion bombardment 220 so as to remove titanium nitride by sputtering off titanium and nitrogen atoms from the bottom portion 208b and redistributing the titanium nitride or titanium on the sidewalls 208a. It should be noted that the material removal of titanium nitride may be substantially restricted to the bottom portion 208b by correspondingly adjusting the directionality of the ion bombardment 220, thereby substantially maintaining the thickness 210a at the bottom of the trench 209 since material sputtered off from the trench bottom may be substantially immediately redistributed to the neighboring horizontal portions, thereby substantially avoiding a net material reduction in the trench 209. The ion bombardment 220 may be carried out prior to the deposition of a further barrier material, such as tantalum or tantalum nitride, whereas, in other embodiments, the material removal of the liner 210 at the bottom 208b may be initiated by, for instance, an initial tantalum ion bombardment prior to or during an initial phase for depositing tantalum or tantalum nitride, or a combination of tantalum and tantalum nitride. To this end, the bias voltage between the ionizing sputter atmosphere and the substrate 201 may be appropriately selected. Corresponding tool settings are well established for re-sputtering of tantalum nitride as will be described later on, or such tool settings may readily be established on the basis of currently available sputter recipes.

FIG. 2c schematically shows the semiconductor structure 200 having formed thereon a barrier layer 212 comprised of a second barrier material. In one particular embodiment, the barrier layer 212 is comprised of tantalum or tantalum nitride, or a combination of tantalum and tantalum nitride. In other embodiments, the barrier layer 212 may comprise any other appropriate material, such as titanium, or any other material compositions that are deemed appropriate for providing the required barrier and adhesion characteristics for the metal to be deposited. As previously explained, the deposition of the barrier material 212 may effectively be promoted by the wetting properties of the underlying titanium nitride liner 210, wherein the requirements with respect to the degree of conformity of the barrier layer 212 are significantly relaxed as the titanium nitride liner 210 reliably covers all surfaces of the dielectric layer 207 even within any voids 211, in case the dielectric layer 207 is comprised of a porous material. Hence, tantalum and/or tantalum nitride may advantageously be deposited by the sputter deposition technique, thereby providing the desired wettability with respect to a subsequent deposition step for forming a copper seed layer. Although the provision of the titanium nitride liner 210 is especially advantageous in combination with a subsequent sputter deposition of a tantalum-containing barrier material, the advantageous effect of the titanium nitride liner 210 may also be used for other materials and other deposition techniques that are compatible with the subsequent filling in of a metal, such as copper. For instance, for future device generations, other complex barrier material compositions may require the deposition of a plurality of different material layers, wherein one or more of these layers may be deposited by sophisticated CVD or ALD techniques if appropriate precursors are available. Also, in these cases, the titanium nitride liner 210 may act as a reliable wetting layer that may efficiently be deposited in a required small thickness.

In another embodiment, the barrier layer 212 may be formed by ionized physical vapor deposition using well-established process recipes, as indicated by reference numeral 221, wherein, during the tantalum and/or tantalum nitride deposition, the process parameters are adjusted so as to obtain a desired thickness 212a at the bottom 208b. For instance, the fraction of ionized tantalum atoms to ionized carrier gas atoms, such as argon, may be decreased or the sputter target may be substantially de-energized so that an argon induced re-sputtering at the bottom 208b occurs, thereby redistributing material from the bottom to the sidewalls of the via 208. In a similar way, the thickness 210a of the titanium nitride liner 210 may be reduced prior to or during an initial phase of the ion bombardment 221, thereby enhancing the conductivity of the via 208 after filling in a metal.

During the redistribution of material of the barrier layer 212 at the via bottom 208b, similarly to what is previously explained with respect to the material redistribution of the titanium nitride liner 210 in the trench 209, the thickness at the trench bottom may remain substantially unaffected by the argon induced re-sputtering at the via bottom 208b. There-after, the semiconductor structure 200 may be prepared for receiving a metal to be filled into the interconnect feature 250. In one particular embodiment, the metal comprises copper and, according to well-established process strategies, a copper seed layer may be deposited prior to filling in the bulk copper by electrochemical deposition methods, such as electroless plating or electroplating. Hence, in one embodiment, a copper seed layer is deposited on the barrier layer 212 by, for instance, ionized physical vapor deposition, wherein, contrary to the conventional ALD barrier layer, an excellent step coverage of the copper seed layer is obtained within the interconnect feature 250 due to the superior wetting properties of the sputter-deposited barrier layer 212. For instance, the above-described process sequence including the sputter deposition of the copper seed layer may be performed in a batch process tool, such as the aforementioned Endura™ from Applied Materials, wherein, due to the highly efficient application of the titanium nitride liner 210 followed by the sputter-deposited tantalum-containing barrier layer 212, a significantly higher throughput is achieved compared to a deposition sequence requiring an ALD process for providing a tantalum-based barrier layer. The thickness of the copper seed layer may be selected in accordance with process requirements and may range, depending on the dimensions of the interconnect feature 250, from approximately 30-100 Å.

In other embodiments, a copper seed layer may be deposited by electroless deposition, wherein, during the deposition of the barrier layer 212, a catalytic material, such as platinum, palladium, cobalt, copper and the like, is incorporated so as to initiate the electrochemical reaction for forming a copper seed layer. Since a catalytic material may not necessarily cover the entire inner surfaces of the interconnect feature 250, typically a relatively small amount of catalytic material is sufficient to provide the desired catalytic behavior. Thereafter, the interconnect feature 250 may be filled with the metal, for instance copper, and excess material may be subsequently removed by etching and/or chemical mechanical polishing, as is also described with reference to FIG. 1c.

FIG. 2d schematically shows the semiconductor structure 200 after the completion of the above-described process sequence. Hence, the semiconductor structure 200 comprises the interconnect feature 250 including a copper seed layer 214 of appropriate thickness and a metal region 213, for instance a copper region, completely filling the trench 209 and the via 208, wherein the formation of irregularities that may be induced by reduced wetting capabilities of a ALD tantalum-based barrier layer may significantly be suppressed. In a real-world device, the copper seed layer 214 may effectively merge with the material formed in the trench. Thus, the copper seed layer 214 may not appear as a distinct, separate layer as depicted in the drawings.

As a result, the present invention provides an improved process technology for forming an efficient, but extremely thin barrier layer for 90 nm technology, 65 nm technology, and even less, wherein an extremely thin titanium nitride liner is conformally deposited by chemical vapor deposition, possibly without requiring a plasma treatment, thereby providing a surface exhibiting an improved wettabilitiy for a subsequently deposited barrier material. As a consequence, well-proven sputter deposition techniques for depositing a barrier layer on the basis of tantalum and/or tantalum nitride may be successfully used, thereby offering a significantly higher throughput when compared to the conventional approach of employing an atomic layer deposition technique. Moreover, the process sequence of forming an interconnect feature including the thin CVD titanium nitride liner may be conveniently integrated into the process sequence of cluster tools and may be therefore effectively implemented in the available hardware of existing semiconductor production lines.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A semiconductor structure, comprising:
a metal region positioned in a dielectric layer;
a first barrier layer comprised of titanium nitride disposed between said dielectric layer and said metal region; and
a second barrier layer disposed between said first barrier layer and said metal region.

2. The semiconductor structure of claim 1, wherein said first barrier layer has a thickness of approximately 20 Å or less.

3. The semiconductor structure of claim 2, wherein said thickness of said first barrier layer is approximately 15 Å or less.

4. The semiconductor structure of claim 1, wherein said dielectric layer has a relative permittivity of approximately 3 or less.

5. The semiconductor structure of claim 4, wherein said dielectric layer comprises a porous material.

6. The semiconductor structure of claim 1, wherein said metal region comprises copper.

7. The semiconductor structure of claim 1, further comprising a first conductive region and a second conductive region formed above said first conductive region, said metal region connecting said first and second conductive regions.

8. The semiconductor structure of claim 1, further comprising a contact region that is in contact with a bottom portion of said metal region.

9. The semiconductor structure of claim 8, wherein said bottom portion of said metal region is substantially devoid of said first barrier layer.

10. The semiconductor structure of claim 1, wherein said second barrier layer comprises tantalum.

11. The semiconductor structure of claim 1, wherein said second barrier layer comprises tantalum nitride.

12. A semiconductor structure, comprising:
an interconnect feature at least partially embedded in an opening in a layer of dielectric material, said interconnect feature including a first barrier layer comprised of titanium nitride formed on sidewalls of said opening and at least one further barrier material formed between said first barrier layer and said interconnect feature.

13. The semiconductor structure of claim 12, wherein said first barrier layer has a thickness of approximately 20 Å or less.

14. The semiconductor structure of claim 12, wherein said first barrier layer has a thickness of approximately 15 Å or less.

15. The semiconductor structure of claim 12, wherein said interconnect feature comprises copper.

16. The semiconductor structure of claim 12, wherein said interconnect feature comprises a bottom portion connecting to a conductive region, whereby said bottom portion is substantially devoid of titanium nitride.

17. The semiconductor structure of claim 12, wherein said at least one further barrier material comprises at least one of tantalum and tantalum nitride.

18. A method, comprising:
depositing a titanium nitride liner over a dielectric layer having an opening formed therein for an interconnect feature;
forming a barrier layer on said deposited titanium nitride liner in said opening; and
filling said opening with a metal.

19. The method of claim 18, wherein said titanium nitride liner is deposited with a thickness of approximately 20 Å or less.

20. The method of claim 19, wherein said titanium nitride liner is deposited with a thickness of approximately 15 Å or less.

21. The method of claim 18, wherein said titanium nitride liner is deposited by a chemical vapor deposition process.

22. The method of claim 18, wherein forming said barrier layer includes depositing said barrier layer by one of physical vapor deposition and atomic layer deposition.

23. The method of claim 22, wherein said barrier layer comprises tantalum or tantalum nitride.

24. The method of claim 18, further comprising removing titanium nitride from a bottom of said opening prior to or during the formation of said barrier layer.

25. The method of claim 18, wherein filling said opening with a metal includes forming a first metal layer by at least one of CVD, PVD and electrochemical deposition and filling in said metal while using said first metal layer as a wetting layer.

26. The method of claim 18, wherein said opening is formed in a low-k dielectric material.

27. The method of claim 26, wherein said low-k dielectric material comprises a porous material.

28. The method of claim 18, wherein forming said barrier layer includes depositing a tantalum-containing barrier material by ionized sputter deposition.

29. The method of claim 28, wherein titanium nitride is removed from a bottom of said opening during said ionized sputter deposition.
